(19) United States
(12) Patent Application Publication
(10) Pub. No.: US 2025/0311429 A1
(43) Pub. Date: Oct. 2, 2025

(54) ARRAY SUBSTRATES AND DISPLAY PANELS

(71) Applicant: TCL CHINA STAR OPTOELECTRONICS TECHNOLOGY CO., LTD., Shenzhen (CN)

(72) Inventor: Minghui HUANG, Shenzhen (CN)

(73) Assignee: TCL CHINA STAR OPTOELECTRONICS TECHNOLOGY CO., LTD., Shenzhen (CN)

(21) Appl. No.: 18/644,154

(22) Filed: Apr. 24, 2024

(30) Foreign Application Priority Data
Apr. 2, 2024 (CN) 202410397026.8

(51) Int. Cl. H01L 27/12

(52) U.S. Cl. CPC H10D 86/60; H10D 86/441; H10D 86/451

(57) ABSTRACT

Array substrates and display panels are provided. The array substrate includes a first wiring layer including first line segments each extending along a first direction, a second wiring layer including second line segments, an insulating layer covering the first and second line segments, and a transfer layer including transfer parts each extending along the first direction. Each second line segment includes a first connecting part extending along the first direction. The insulating layer includes first via hole groups each including at least one first via hole and second via hole groups each including at least one second via hole. The first line segment and the transfer part are connected at the first via hole. The first connecting part and the transfer part are connected at the second via hole. The first via hole groups and the second via hole groups are alternately arranged along the first direction.

### CROSS-REFERENCE TO RELATED APPLICATION

This application claims priority to Chinese Patent Application No. 202410397026.8, filed on Apr. 2, 2024, the disclosure of which is incorporated herein by reference in its entirety.

### TECHNICAL FIELD

The present disclosure relates to the field of display technologies, and in particular, to array substrates and display panels.

### BACKGROUND

Currently, display panels those use a gate driving circuit on an array substrate to replace a gate driver chip, form timing, and realize the progressive scanning function, have become mainstream. As refresh rate requirements of display panels increase, a number of signal lines (such as timing signal lines) required for the gate driving circuit is also increased accordingly so as to improve the problem of load increase caused by the high refresh rate. Signal transfer via holes of each signal line are arranged in multiple columns (as shown by 111′ and 112′ in FIG. 1 to FIG. 3) in a width direction of a wiring segment of the signal line located on one side of the gate driving circuit, which causes it difficult to reduce widths of some wiring segments of each signal line, so that it is difficult to narrow a boundary width of the array substrate.

### SUMMARY

In view of above, array substrates are provided according to embodiments of the present disclosure. The array substrate includes a first wiring layer, a second wiring layer, an insulating layer, and a transfer layer. The first wiring layer includes first line segments each extending along a first direction. The second wiring layer is arranged in a different layer from the first wiring layer and includes second line segments. Each of the second line segments includes a first connecting part extending along the first direction. The insulating layer covers the first line segments and the second line segments. The transfer layer is disposed on one side of the insulating layer away from the first wiring layer and includes transfer parts each extending along the first direction. The insulating layer includes a plurality of first via hole groups and a plurality of second via hole groups. Each of the plurality of first via hole groups includes one or more first via holes, and each of the plurality of second via hole groups includes one or more second via holes. The first line segments and the transfer parts are connected at the first via holes, and the first connecting parts and the transfer parts are connected at the second via holes. The first via hole groups and the second via hole groups are arranged alternately along the first direction.

Display panels are also provided according to embodiments of the present disclosure. The display panel includes the array substrate as described above.

### BRIEF DESCRIPTION OF THE DRAWINGS

In order to explain the technical solutions in the embodiments of the present disclosure more clearly, the following will briefly introduce the drawings needed to describe the embodiments. Obviously, the drawings in the following description are only some embodiments of the present disclosure. For those skilled in the art, other drawings may be obtained based on these drawings without exerting creative efforts.

FIG. 1 is a first structural schematic view of signal transfer via holes in related art.

FIG. 2 is a second structural schematic view of signal transfer via holes in the related art.

FIG. 3 is a third structural schematic view of signal transfer via holes in the related art.

FIG. 4 is a schematic structural view of an array substrate provided by an embodiment of the present disclosure.

FIG. 5 is a first structural schematic view of a first line segment and a second line segment of the array substrate provided by an embodiment of the present disclosure.

FIG. 6 is a second structural schematic view of the first line segment and the second line segment of the array substrate provided by an embodiment of the present disclosure.

FIG. 7 is a schematic cross-sectional structural view along a line AA′ in FIG. 4.

FIG. 8 is a schematic cross-sectional structural view along a line BB′ in FIG. 4.

FIG. 9 is a second structural schematic view of the first line segment and the second line segment of the array substrate provided by an embodiment of the present disclosure.

FIG. 10 is a third structural schematic view of the first line segment and the second line segment of the array substrate provided by an embodiment of the present disclosure.

FIG. 11 is a fourth structural schematic view of the first line segment and the second line segment of the array substrate provided by an embodiment of the present disclosure.

FIG. 12 is a fifth structural schematic view of the first line segment and the second line segment of the array substrate provided by an embodiment of the present disclosure.

FIG. 13 is a schematic diagram showing a current density of a structure having the first line segment and the second line segment of the array substrate shown in FIG. 9.

FIG. 14 is a schematic diagram showing a current density of a structure having the first line segment and the second line segment of the array substrate shown in FIG. 5.

FIG. 15 is a schematic structural view of a thin film transistor of the array substrate provided by an embodiment of the present disclosure.

FIG. 16 is a first structural schematic view of a display device provided by an embodiment of the present disclosure.

FIG. 17 is a second structural schematic view of the display device provided by an embodiment of the present disclosure.

### DETAILED DESCRIPTION

The technical solutions in the embodiments of the present disclosure will be clearly and completely described below with reference to the accompanying drawings in the embodiments of the present disclosure. Obviously, the described embodiments are only some of the embodiments of the present disclosure, but not all of the embodiments. Based on the embodiments in the present disclosure, all other embodiments obtained by those skilled in the art without making creative efforts fall within the protection scope of the present disclosure. In addition, it should be understood that the specific embodiments described here are only used to illustrate and explain the invention, and are not used to limit the invention. In the present disclosure, unless otherwise specified, the orientational terms used such as “upper” and “lower” usually refer to the upper and lower positions of the device in actual use or working conditions, specifically the orientations in the drawings. The terms “inside” and “outside” refer to the outline of the device.

Currently, since the signal transfer via holes of the signal line required for the gate driving circuit are arranged in multiple columns in the width direction of the wiring segment of the signal line located on one side of the gate driving circuit, it is difficult to reduce widths of some wiring segments of each signal line, and it is difficult to narrow the boundary width of the array substrate.

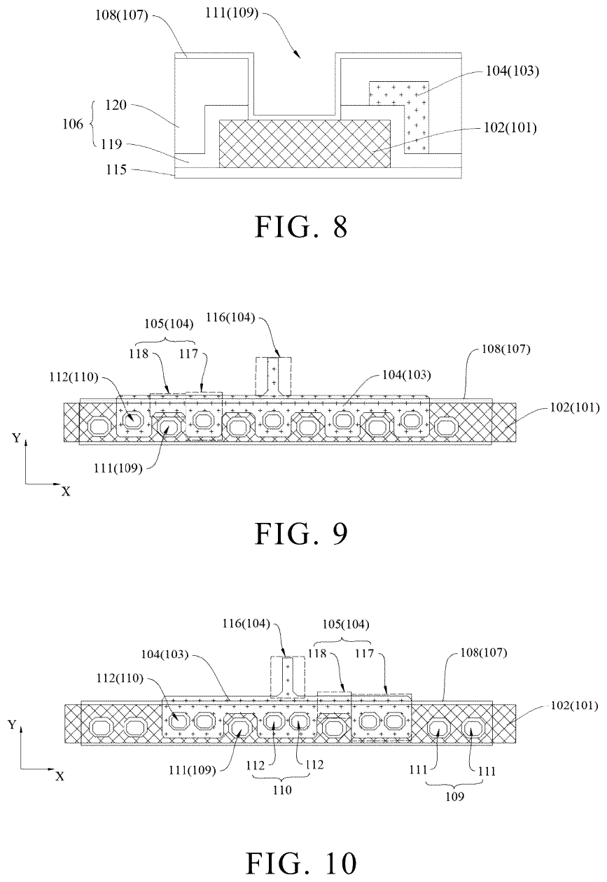

Referring to FIG. 4 to FIG. 12, embodiments of the present disclosure provide array substrates 100. The array substrate 100 includes a first wiring layer 101, a second wiring layer 103, an insulating layer 106, and a transfer layer 107.

The first wiring layer 101 includes first line segments 102 each extending along a first direction X.

The second wiring layer 103 is arranged in a different layer from the first wiring layer 101. The second wiring layer 103 includes second line segments 104, and each second line segment 104 includes a first connecting part 105 extending along the first direction X.

The insulating layer 106 covers the first line segments 102 and the second line segments 104.

The transfer layer 107 is located on one side of the insulating layer 106 away from the first wiring layer 101. The transfer layer 107 includes transfer parts 108, and each transfer part 108 extends along the first direction X.

The insulating layer 106 includes a plurality of first via hole groups 109 and a plurality of second via hole groups 110. Each of the first via hole groups 109 includes at least one first via hole 111. Each of the second via hole groups 110 includes at least one second via hole 112. The first line segment 102 and the transfer part 108 are connected at the first via hole 111, and the first connecting part 105 and the transfer part 108 are connected at the second via hole 112. The first via hole groups 109 and the second via hole groups 110 are arranged alternately along the first direction X.

In the embodiments of the present disclosure, by alternately arranging the first via hole groups 109 and the second via hole groups 110 of the array substrate 100 along the extending direction of the first line segment 102, a total width of the first line segments 102 and the connecting parts 105 of the second line segments 104 is reduced, thereby narrowing a boundary width of the display panel applying the array substrate 100.

The technical solutions of the present disclosure will now be described with reference to specific embodiments.

Referring to FIG. 4, in this embodiment, the array substrate 100 further includes a gate driving circuit 113 located on one side of the first line segments 102 in a second direction Y. The gate driving circuit 113 includes a plurality of cascaded gate driving units 114. The plurality of gate driving units 114 are arranged along the first direction X. The second direction Y intersects the first direction X.

In this embodiment, the total width of the first connecting parts 105 and the first line segments 102 is a distance in the second direction Y between one side surface of the first line segments 102 away from the gate driving units 114 and one side surface of the first connecting parts 105 close to the gate driving units 114.

Referring to FIG. 4, in this embodiment, the array substrate 100 includes a display area AA and a frame area NA surrounding the display area AA. The gate driving circuit 113, the first line segments 102, and the second line segments 104 are arranged in the frame area NA, and the first line segments 102 and the second line segments 104 are arranged on one side of the gate driving circuit 113 away from the display area AA.

Referring to FIG. 6 to FIG. 8 and FIG. 15, in some embodiments, the array substrate 100 further includes a substrate 115. The second wiring layer 103 is located on one side of the first wiring layer 101 away from the substrate 115. The transfer layer 107 is located on one side of the second wiring layer 103 away from the substrate 115.

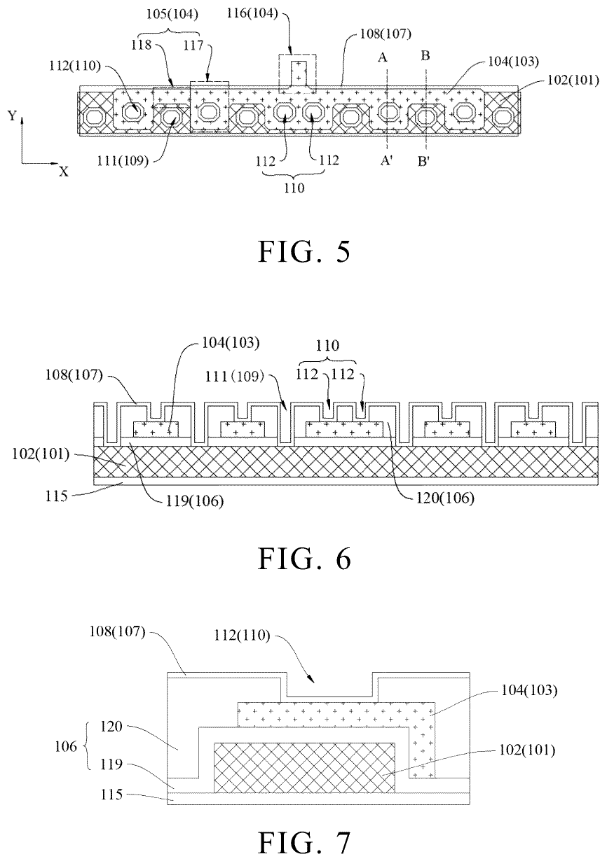

Referring to FIG. 5 and FIG. 9 to FIG. 12, in some embodiments, each of the second line segments 104 further includes second connecting parts 116 each extending along the second direction Y. The first connecting part 105 is connected to the second connecting parts 116, and the second connecting parts 116 are connected to the gate driving circuit 113.

Referring to FIG. 4, in some embodiments, the gate driving units 114 are connected to the second connecting parts 116 in an one-to-one correspondence.

Referring to FIG. 5 and FIG. 9 to FIG. 12, in some embodiments, the first connecting part 105 includes first sub-parts 117 and second sub-parts 118. Along the first direction X, each of the second sub-parts 118 is connected between two adjacent first sub-parts 117. An orthographic projection of the second via hole group 110 on the second wiring layer 103 is located within the first sub-parts 117. The second connecting part 116 is connected to the first sub-part 117.

In some embodiments, a width of the first sub-part 117 is a distance between opposite two lateral surfaces of the first sub-part 117 in the second direction Y, and a width of the second sub-part 118 is a distance between opposite two lateral surfaces of the second sub-part 118 in the second direction Y. The width of the first sub-part 117 is greater than the width of the second sub-part 118. The first via hole groups 109 are located on one side of the second sub-parts 118 away from the gate driving circuit 113, and an orthographic projection of the first via hole groups 109 on the first wiring layer 101 is located within the first line segments 102. Since the width of the first sub-part 117 is greater than the width of the second sub-part 118, and the first via hole groups 109 are provided on one side of the second sub-parts 118 away from the driving circuit, it is beneficial to reducing the width of the line segments 102, which narrows the boundary width of the display panel.

In some embodiments, the first sub-part 117 includes a first end close to the driving circuit, and the second sub-part 118 is integrated with the first end. That is, the second sub-part 118 is disposed between two adjacent first sub-parts 117 and located on sides of the first sub-parts 117 close to the gate driving unit 114, so as to allow sufficient space for the first via hole 111. In some embodiments, one lateral surface of the second sub-part 118 close to the gate driving unit 114 and one lateral surface of the first sub-part 117 close to the gate driving unit 114 are located in the same plane, so as to maximize the space provided for the first via hole 111.

In some embodiments, the first connecting part 105 includes openings located on one side of the second sub-parts 118 away from the gate driving circuit 113, and the first via hole 111 is correspondingly located in the opening. An orthographic projection of the first connecting part 105 on the first wiring layer 101 presents a “comb shape”.

Referring to FIG. 5 and FIG. 9 to FIG. 12, in some embodiments, the orthographic projection of the first connecting part 105 on the first wiring layer 101 partially overlaps the first line segment 102, so as to reduce the total width of the first connecting parts 105 and the first line segments 102 in the second direction Y, which is beneficial to reduce the boundary width of the display panel having the array substrate 100.

In some embodiments, the array substrate 100 includes first class signal lines including the first line segments 102 and the second line segments 104. Each of the first class signal lines includes one first line segment 102 and one first connecting part 105. That is, the first line segments 102 and the first connecting parts 105 are provided in an one-to-one correspondence.

In some embodiments, in the second direction Y, one lateral surface of each first connecting part 105 close to the gate driving circuit 113 is located between one lateral surface of the corresponding first line segment 102 close to the driving circuit 113 and the gate driving circuit 113. That is, in the second direction Y, one side edge of each first connecting part 105 close to the gate driving circuit 113 is arranged beyond one side edge of the corresponding first line segment 102 close to the gate driving circuit 113. The above arrangements are helpful to prevent product quality problems caused by process fluctuations, such as problems affecting product quality due to undercut problems.

Referring to FIG. 12, in some embodiments, in the second direction Y, one lateral surface of each first connecting part 105 away from the gate driving circuit 113 is located on one side of one lateral surface of the corresponding first line segment 102 away from the gate driving circuit 113 away from the gate driving circuit 113. That is, in the second direction Y, one side edge of each first connecting part 105 away from the gate driving circuit 113 is arranged beyond one side edge of the corresponding first line segment 102 113 away from the gate driving circuit 113.

In some embodiments, in the second direction Y, one lateral surface of each first connecting part 105 away from the gate driving circuit 113 is located between two opposite lateral surfaces of the first line segment 102 in the second direction Y, which is beneficial to control a total width of each first line segment 102 and the corresponding first connecting part 105 in the second direction Y, and is beneficial to reducing the boundary width of the display panel having the array substrate 100.

In some embodiments, the transfer parts 108 are provided in an one-to-one correspondence with the first connecting parts 105, and the transfer parts 108 are provided in an one-to-one correspondence with the first line segments 102. In the second direction Y, one lateral surface of each transfer part 108 close to the gate driving circuit 113 is located on one side of the corresponding first connecting part 105 away from the first line segment 102. In the second direction Y, one lateral surface of each transfer part 108 away from the gate driving circuit 113 is located on one side of the corresponding first line segment 102 away from the gate driving circuit 113. That is, in the second direction Y, a width of each transfer part 108 is greater than the total width of the corresponding first connecting part 105 and the first line segment 102. Through the above arrangements, it is conducive to full contact between the transfer part 108 and the first line segment 102 and full contact between the transfer part 108 and the first connecting part 105, which improves the problem of increased loading caused by reduced width of the first line segment 102.

In some embodiments, the first via hole 111 exposes the first line segment 102, and the transfer part 108 extends into the first via hole 111 and contacts the first line segment 102, so that the connection between the transfer part 108 and the first line segment 102 is realized. The second via hole 112 exposes the first connecting part 105, and the transfer part 108 extends into the second via hole 112 and contacts the first connecting part 105, so that the connection between the transfer part 108 and the first connecting part 105 is realized. Through the alternate arrangement of the first via hole groups 109 and the second via hole groups 110 in the first direction, while reducing the width of the first line segment 102, a contact area between the transfer part 108 and the first line segment 102 and a contact area between the transfer part 108 and the second line segment 104 are increased, which improves the problem of increased loading caused by the reduction in the width of the first line segment 102.

Referring to FIG. 6 to FIG. 8, in some embodiments, when the transfer part 108 is located on one side of the first connecting part 105 away from the first line segment 102, a depth of the first via hole 111 is greater than a depth of the second via hole 112.

Referring to FIG. 6 to FIG. 8, in some embodiments, the insulating layer 106 includes a first insulating sub-layer 119 and a second insulating sub-layer 120. The first insulating sub-layer 119 is located between the first wiring layer 101 and the the second wiring layer 103, and the second insulating sub-layer 120 is located between the second wiring layer 103 and the transfer layer 107. The first via hole 111 penetrates the first insulating sub-layer 119 and the second insulating sub-layer 120, and the second via hole 112 penetrates the second insulating sub-layer 120.

Referring to FIG. 5, in some embodiments, a number of the second via holes 112 in the second via hole group 110 corresponding to the first sub-part 117 connected to the second connecting part 116 of the second line segment 104 is more than a number of the second via holes 112 in the second via hole group 110 corresponding to the first sub-part 117 that is not connected to the second connecting part 116 of the second line segment 104. Specifically, in the second via hole group 110 corresponding to the first sub-part 117 connected to the second connecting part 116 of the second line segment 104, the number of the second via holes 112 is greater than or equal to 2. The above arrangement is conducive to increasing the contact area between the transfer part 108 and the first connecting part 105, thereby slowing down the thermal effect of the current and improving the product quality of the array substrate 100. At the same time, in the second via hole group 110 corresponding to the first sub-part 117 connected to the second connecting part 116 of the second line segment 104, because the number of the second via holes 112 is greater than or equal to 2, on a condition that there is a problem such as poor contact between the first connecting part 105 and the transfer part 108 in one of the second via holes 112, a normal operation of the array substrate 100 can be maintained through connection between the first connecting part 105 and the transfer part 108 in the other or more second via holes 112, improving the service life and product quality of the array substrate 100.

In some embodiments, an area of an orthographic projection of the second via holes 112 in the second via hole group 110 corresponding to the first sub-part 117 connected to the second connecting part 116 of the second line segment 104 on the transfer part 108 is greater than an area of an orthographic projection of the second via holes 112 in the second via hole group 110 corresponding to the first sub-part 117 that is not connected to the second connecting part 116 of the second line segment 104 on the transfer part 108, which is conducive to increasing the contact area between the transfer part 108 and the first connecting part 105, thereby slowing down the thermal effect of the current and improving the product quality of the array substrate 100.

Referring to FIG. 10, in some embodiments, in the first direction X, the number of the second via holes 112 in any second via hole group 110 is greater than or equal to 2.

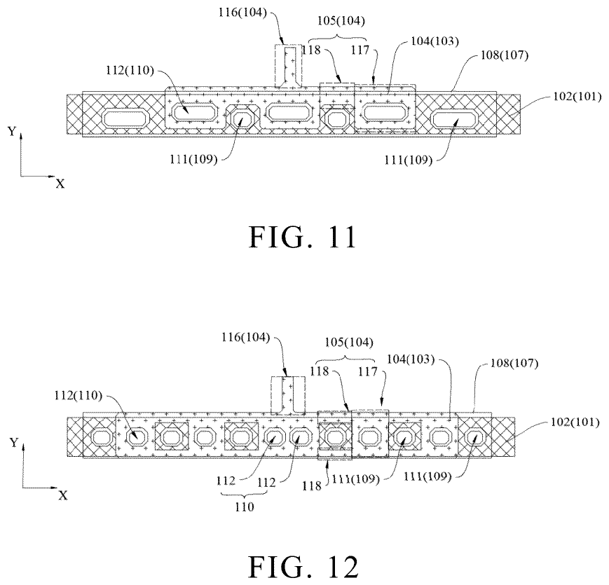

Referring to FIG. 5, FIG. 9, FIG. 11, and FIG. 12, in some embodiments, in the first direction X, the number of the first via holes 111 in any of the first via hole groups 109 is greater than or equal to 1.

Referring to FIG. 9, in some embodiments, in the first direction X, the number of the first via holes 111 in each of the first via hole groups 109 is one, and the number of the second via holes 112 in each of the via hole groups 110 is one. That is, in the first direction X, the first via holes 111 and the second via holes 112 are arranged alternately one by one.

Referring to FIG. 5, FIG. 10 to FIG. 12, in some embodiments, a sum of areas of orthographic projections of the second via holes 112 in the second via hole group 110 corresponding to any first sub-part 117 connected to the second connecting part 116 of the second line segment 104 on the transfer part 108 is greater than a sum of areas of orthographic projections of the first via holes 111 in one of at least some first via hole groups 109 on the transfer part 108. By increasing the total area of the orthographic projections of the second via holes 112 corresponding to the first sub-part 117 connected to the second connecting part 116 on the transfer part 108, it is beneficial to increase the contact area between the transfer part 108 and the first connecting part 105, thereby reducing the thermal effect of the current and improving the product quality of the array substrate 100.

In some embodiments, the first via hole groups 109 may be divided into a first part of first via hole groups and a second part of first via hole groups. A sum of areas of orthographic projections of the first via holes 111 in one first via hole group of the first part of first via hole groups on the transfer part 108 is greater than a sum of areas of orthographic projections of the first via holes 111 in one first via hole group of the second part of first via hole groups on the transfer part 108.

In some embodiments, an orthographic projection of the first via hole 111 on a first plane at least partially overlaps an orthographic projection of the second via hole 112 on the first plane, and the first plane is perpendicular to a plane where the array substrate 100 is located, and the first plane is perpendicular to the first direction X. It is beneficial to reducing the space occupied by the first via hole 111 and the second via hole 112 in the second direction Y, thereby reducing the width of the first line segment 102 and the first connecting part 105 in the second direction Y, and narrowing the boundary width of the display panel.

Referring to FIG. 5 and FIG. 9 to FIG. 12, in some embodiments, the number of the first via holes 111 in the second direction Y in each first via hole group 109 is one. That is, when the number of the first via holes 111 in any first via hole group 109 is greater than or equal to 2, all the first via holes 111 in the first via hole group 109 are arranged along the first direction X. The number of the first via holes 111 in each second via hole group 110 in the second direction Y is one. That is, when the number of the second via holes 112 in any second via hole group 110 is greater than or equal to 2, all the second via holes 112 in the second via hole group 110 are arranged along the first direction X. By arranging the first via holes 111 and the second via holes 112 only along the first direction, the space occupied by the first via holes 111 and the second via holes 112 in the direction Y is reduced, thereby reducing the width of the first line segment 102 and the first connecting part 105 in the second direction Y, and narrowing the boundary width of the display panel.

Referring to Table 1, on a condition that the sum of areas of orthographic projection of all the first via holes 111 on the transfer part 108 is kept the same, and the sum of areas of orthographic projections of all the second via holes 112 on the transfer part 108 is kept the same, for structures applying the first line segment 102 and the second line segment 104 respectively illustrated in FIG. 2, FIG. 5, FIG. 9 to FIG. 12, a maximum current value and resistance data obtained through simulation test are shown in Table 1 below:

TABLE 1

| Structure | FIG. 2 | FIG. 5 | FIG. 9 | FIG. 10 | FIG. 11 | FIG. 12 |
|---|---|---|---|---|---|---|
| Maximum current value | 6.46E+09 | 1.92E+10 | 1.92E+10 | 1.08E+10 | 1.09E+10 | 1.97E+10 |
| Resistance/Ω | 22.45 | 7.57 | 7.55 | 13.45 | 13.31 | 7.33 |

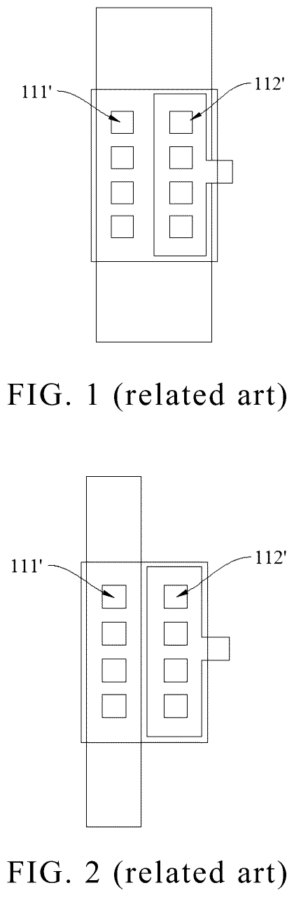

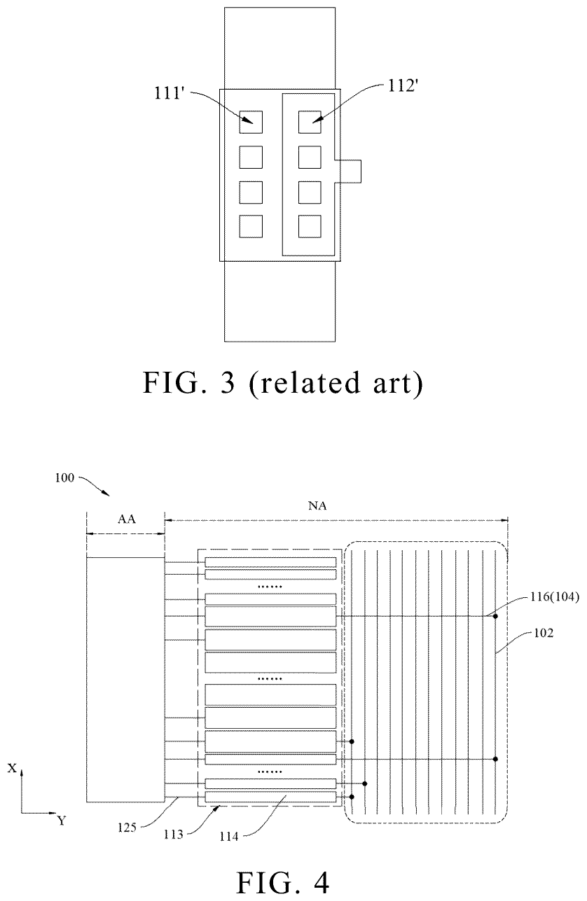

It can be seen from the results in Table 1 that when the structure having the first line segment 102 and the second line segment 104 of the array substrate 100 provided by the embodiments of the present disclosure is applied, compared with the related art illustrated in FIG. 1, the resistance value is significantly improved and the maximum current value has also been improved to a certain extent. At the same time, when the structures having the first line segment 102 and the second line segment 104 respectively illustrated in FIG. 5, FIG. 9, FIG. 11, and FIG. 12 are applied, the maximum current value and resistance value are slightly better than those when the structure having first line segment 102 and the second line segment 104 illustrated in FIG. 10 is applied. This shows that when the number of first via holes 111 in each first via hole group 109 in the first direction is less, the structure has better maximum current value and resistance value. In addition, when the structures having the first line segment 102 and the second line segment 104 respectively illustrated in FIG. 5 and FIG. 12 are applied, the maximum current value and resistance value are not much different. When the structure having the first line segment 102 and the second line segment 104 illustrated in FIG. 5 is applied, the space occupied by the first line segment 102 and the first connecting part 105 in the second direction is effectively reduced, which is more conducive to reducing the boundary width of the display panel including the array substrate 100.

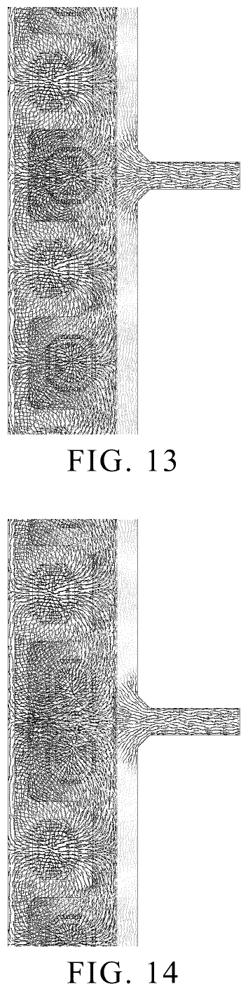

Referring to FIG. 13 and FIG. 14, FIG. 13 is a schematic diagram showing a current density of a structure having the first line segment and the second line segment of the array substrate shown in FIG. 9, and FIG. 14 is a schematic diagram showing a current density of a structure having the first line segment and the second line segment of the array substrate shown in FIG. 5. According to Q=I²Rt, Q represents heat, I represents current, R represents resistance, and t represents time. When R and t are the same, the greater the current I, the greater the heat generation. Comparing FIG. 13 with FIG. 14, it can be seen that the number of second via holes 112 in the second via hole group corresponding to the first connecting part 105 connected to the second connecting part 116 is larger, the current density is effectively dispersed, local overheating is avoided, and the reliability of the array substrate 100 is improved.

In some embodiments, one first connecting part 105 is connected to multiple second connecting parts 116. In the first direction X, the first sub-parts 117 of one first connecting part 105 are respectively connected to the multiple second connecting parts 116. Specifically, one second connecting part 116 is connected to one of the first sub-parts 117 of one first connecting part 105, and one second connecting part 116 is connected to one of the gate driving units 114. One first connecting part 105 and all the second connecting parts 116 connected to the first connecting part 105 form the second line segment 104.

In some embodiments, in the first direction X, in the same first connecting part 105, at least one first sub-part 117 that is not connected to the second connecting part 116 is provided between the first sub-parts 117 connected to the second connecting parts 116. The arrangement of the first sub-parts 117 that are not connected to the second connecting part 116 is conducive to increasing the contact area between the transfer part 108 and the second line segment 104, improving the problem of increased loading caused by the reduction in the width of the first line segment 102, and reducing signal delay.

In some embodiments, in the first direction X, in the same first connecting part 105, the number of the first sub-parts 117 those are not connected to the second connecting parts 116 and provided between two adjacent first sub-parts 117 connected to the second connecting parts 116 is the same.

In some embodiments, a timing signal is transmitted to the gate driving circuit 113 through the first line segment 102 and the second line segment 104. The array substrate 100 includes the plurality of first line segments 102 arranged along the second direction Y, and the adjacent first line segments 102 in the second direction Y can receive different timing signals.

In some embodiments, in the first direction X, two adjacent second connecting parts 116 connected to the same first connecting part 105 are connected to non-adjacent gate driving units 114.

In some embodiments, in the first direction X, adjacent gate driving units 114 are connected to different first connecting parts 105 through different second connecting parts 116, thereby receiving different timing signals.

In some embodiments, along a direction from the first line segment 102 to the gate driving unit 114, the number of the first via holes 111 between different first line segments 102 and the corresponding transfer parts 108 decreases. That is, in the second direction Y, the number of the first via holes 111 between the farthest one of the plurality of first line segments 102 from the gate driving circuit 113 and the corresponding transfer parts 108 is greater than the number of the first via holes 111 between the closest one of the plurality of first line segments 102 to the gate driving circuit 113 and the corresponding transfer parts 108. Along the direction from the first line segment 102 to the gate driving unit 114, the number of the second via holes 112 between different first connecting parts 105 and the corresponding transfer parts 108 decreases. That is, in the second direction Y, the number of the second via holes 112 between the farthest one of the plurality of first connecting parts 105 from the gate driving circuit 113 and the corresponding transfer parts 108 is greater than the number of the second via holes 112 between the closest one of the plurality of first connecting parts 105 to the gate driving circuit 113 and the corresponding transfer parts 108. Because along the direction from the first line segment 102 to the gate driving unit 114, the second connecting part 116 connected to the farthest one of the plurality of first connecting parts 105 from the gate driving circuit 113 has the longest length, and the second connecting part 116 connected to the closest one of the plurality of first connecting parts 105 to the gate driving circuit 113 has the shortest length, the above adjustment is conducive to improving the delay difference of signals transmitted through different first line segment 102 while improving the problem of increased loading caused by the reduction in the width of the first line segment 102, which is beneficial to the uniformity of charging of a thin film transistor in the array substrate 100.

In some embodiments, the longer the length of the second connecting part 116 in the second direction Y, the wider the width of the second connecting part 116 in the first direction X. That is, the width of the second connecting part 116 connected to the farthest one of the plurality of first connecting parts 105 from the gate driving circuit 113 in the second direction Y is greater than the width of the second connecting part 116 connected to the closest one of the plurality of first connecting parts 105 to the gate driving circuit 113 in the second direction Y.

Because along the direction from the first line segment 102 to the gate driving unit 114, the second connecting part 116 connected to the farthest one of the plurality of first connecting parts 105 from the gate driving circuit 113 has the longest length, and the second connecting part 116 connected to the closest one of the plurality of first connecting parts 105 to the gate driving circuit 113 has the shortest length, the above adjustment minimizes the difference in resistances of the second connecting parts 116 connected to different first connecting parts 105, which is conducive to improving the delay difference of signals transmitted through different first line segment 102 while improving the problem of increased loading caused by the reduction in the width of the first line segment 102, and is beneficial to the uniformity of charging of a thin film transistor in the array substrate 100.

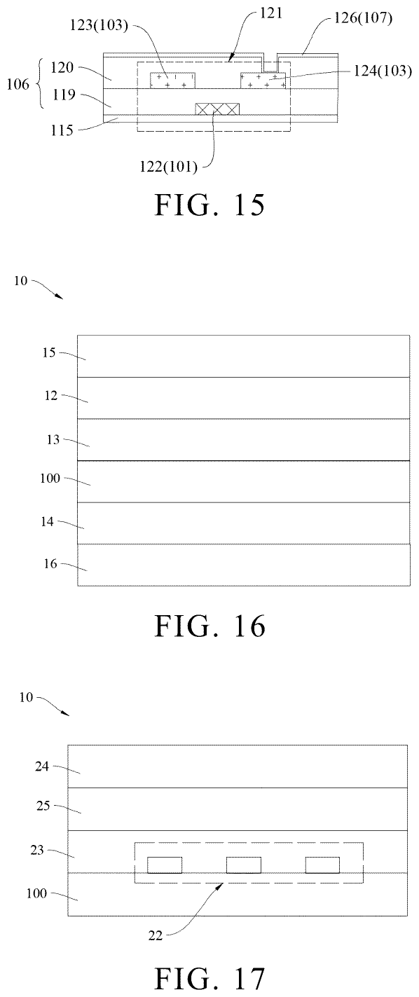

Referring to FIG. 15, in some embodiments, the array substrate 100 further includes thin film transistors 121. The thin film transistor 121 includes a gate 122, a source 123, and a drain 124. The source 123 and the gate 122 are arranged in different layers. The source 123 and the drain 124 are arranged in the same layer. The gate 122 is located in the first wiring layer 101, and the source 123 and the drain 124 are located in the second wiring layer 103. The first line segments 102 and the gate 122 may be formed of the same material and process, so as to simplify the process and reduce the production costs. Similarly, the second line segments 104, the source 123, and the drain 124 may be formed of the same material and the same process, so as to simplify the process and reduce the production costs.

In some embodiments, the thin film transistor 121 further includes a semiconductor located between the substrate 115 and the gate 122, and the semiconductor may be formed of polysilicon or metal oxide (such as indium gallium zinc oxide). An orthographic projection of the gate 122 on the semiconductor overlaps a channel region. The semiconductor is divided into the channel region, and a source region and a drain region formed on both sides of the channel region. The array substrate 100 further includes a first gate insulating layer covering the semiconductor.

In some embodiments, a material of the gate 122 and the first line segment 102 may be multiple layers or single layer selected from low-resistance materials such as Al, Ti, Mo, Cu, Ni, or alloys thereof, or other materials with conductive properties.

Referring to FIG. 15, in some embodiments, the first insulating sub-layer 119 is located between the source 123 and the gate 122, and the second insulating sub-layer 120 is located on one side of the source 123 away from the gate 122. The first insulating sub-layer 119 and the first gate insulating layer include a source contact hole and a drain contact hole, and the source region and the drain region are respectively exposed through the source contact hole and the drain contact hole. The source 123 extends into the source contact hole and contacts the semiconductor in the source region. The drain 124 extends into the drain contact hole and contacts the semiconductor in the drain region.

In some embodiments, the second line segment 104, the source 123, and the drain 124 may be multiple layers or single layer selected from low-resistance materials such as Al, Ti, Mo, Cu, Ni, or alloys thereof, or other materials with conductive properties.

In some embodiments, some of the thin film transistors 121 located in the gate driving unit 114 are connected to the second connecting parts 116 to receive corresponding signals (such as: timing signals, etc.).

In some embodiments, the array substrate 100 further includes pixel units located in the display area AA. The pixel units are arranged in an array along a row direction and a column direction. The first direction X may be parallel to the column direction, and the second direction Y may be parallel to the row direction.

Referring to FIG. 4, in some embodiments, the array substrate 100 further includes a plurality of gate signal lines 125 each extending along the second direction Y. The gate signal lines 125 are arranged along the first direction X. Each of the gate signal lines 125 connects one gate driving unit 114 and one row of the pixel units.

Referring to FIG. 15, in some embodiments, the array substrate 100 further includes a pixel electrode 126 and/or a common electrode. The pixel electrode 126 or the common electrode is located in the transfer layer 107. That is, the transfer parts 108 and the pixel electrode 126 are arranged on the same layer, or the transfer parts 108 and the common electrode are arranged on the same layer, so as to simplify the manufacturing process of the array substrate 100 and reduce the production costs. The pixel electrode 126 is connected to the thin film transistors 121. Specifically, the second insulating sub-layer 120 is located between the pixel electrode 126 and the source 123. The second insulating sub-layer 120 includes a pixel electrode contact hole, and the pixel electrode contact hole exposes the source 123 or the drain 124. The pixel electrode 126 extends to the pixel electrode contact hole and contacts with the source 123 or the drain 124.

In some embodiments, the transfer parts 108, the pixel electrode 126, and the common electrode may be selected from transparent conductive materials, such as indium tin oxide (ITO), etc.

In some embodiments, the substrate 115 may be a hard substrate, such as a glass substrate. Alternatively, the substrate 115 may be a flexible substrate. For example, the substrate 115 may be a substrate made of polyimide. When the substrate 115 is a flexible substrate, the substrate 115 may be formed of multi-layer sub-substrates made of the same material, such as polyimide, and adjacent sub-substrates are bonded by an adhesive sub-layer.

In the array substrate 100 disclosed in the embodiments of the present disclosure, by alternately arranging the first via hole groups 109 and the second via hole groups 110 along the extending direction of the first line segment 102, the total width of the first line segments 102 and the connecting parts 105 of the second line segments 104 is reduced, thereby narrowing the boundary width of the display panel.

Referring to FIG. 16 and FIG. 17, embodiments of the present disclosure also provide display panels 10. The display panel 10 includes the array substrate 100 as described above.

A specific structure of the array substrate 100 can be referred to any of the above embodiments of the array substrate and the accompanying drawings, and will not be described again here.

In some embodiments, the display panel 10 may be a liquid crystal display panel or a self-luminous display panel.

Referring to FIG. 16, when the display panel 10 is a liquid crystal display panel, the display panel 10 further includes a color filter substrate 12 disposed opposite to the array substrate 100, a liquid crystal layer 13 disposed between the color filter substrate 12 and the array substrate 100, a first polarizer layer 14 disposed on one side of the array substrate 100 away from the color filter substrate 12, and a second polarizer layer 15 disposed on one side of the color filter substrate 12 away from the array substrate 100. When the display panel 10 is the liquid crystal display panel, the display panel 10 further includes a backlight assembly 16, and the backlight assembly 16 is disposed on one side of the first polarizer layer 14 away from the array substrate 100 or on the side of the second polarizer layer 15 away from the color filter substrate 12.

Referring to FIG. 17, when the display panel 10 is a self-luminous display panel, the display panel 10 further includes a light-emitting device layer 22 disposed on one side of the array substrate 100 away from the substrate 115. The light-emitting device layer 22 includes multiple light-emitting devices, and the light-emitting devices may include organic light-emitting diodes (OLED), or may include Micro LED or Mini LED, which are not specifically limited here. When the display panel 10 is the self-luminous display panel, the display panel 10 further includes an encapsulation layer 23 disposed on one side of the light-emitting device layer 22 away from the array substrate 100. The encapsulation layer 23 may include a first inorganic encapsulation sub-layer, a first organic encapsulation sub-layer, and a second inorganic encapsulation sub-layer. When the display panel 10 is the self-luminous display panel, the display panel 10 further includes a cover layer 24 disposed on one side of the encapsulation layer 23 away from the array substrate 100. When the display panel 10 is the self-luminous display panel, the display panel 10 further includes a polarizer layer 25 disposed between the encapsulation layer 23 and the cover layer 24.

The display panel 10 may be applied to display terminals such as mobile phones, tablets, televisions, computers, virtual reality display devices, and augmented reality display devices.

Embodiments of the present disclosure disclose the array substrates and the display panels. The array substrate includes the first wiring layer, the second wiring layer, the insulating layer, and the transfer layer. The insulating layer covers the first line segments and the second line segments. The transfer layer is located on one side of the insulating layer away from the first wiring layer. The transfer layer includes the transfer parts. The insulating layer includes the first via hole groups and the second via hole groups. Each first via hole group includes at least one first via hole. Each second via hole group includes at least one second via hole. The first line segment and the transfer part are connected at the first via hole. The second wiring layer includes the second line segments, and the first connecting part of the second line segment is connected to the transfer part at the second via hole. The first via hole groups and the second via hole groups are alternately arranged along the first direction. In the present disclosure, by alternately arranging the first via hole groups and the second via hole groups of the array substrate along the extending direction of the first line segment, the total width of the first line segments and the connecting parts of the second line segments is reduced, thereby narrowing the boundary width of the display panel applying the array substrate.

The array substrates and the display panels provided by the embodiments of the present disclosure have been introduced in detail. Specific examples are used in this paper to illustrate the principles and implementation methods of the present disclosure. The description of the above embodiments is only for help understand the method and core ideas of the present disclosure. At the same time, for those skilled in the art, there will be changes in the specific implementation and application scope based on the ideas of the present disclosure. In summary, the content of this description should not be understood as a limitation of the present disclosure.

What is claimed is:

1. An array substrate, comprising:
a first wiring layer, comprising first line segments each extending along a first direction;
a second wiring layer, arranged in a different layer from the first wiring layer and comprising second line segments, wherein each of the second line segments comprises a first connecting part extending along the first direction;
an insulating layer, covering the first line segments and the second line segments; and
a transfer layer, disposed on one side of the insulating layer away from the first wiring layer and comprising transfer parts each extending along the first direction,
wherein the insulating layer comprises a plurality of first via hole groups and a plurality of second via hole groups, each of the plurality of first via hole groups comprises one or more first via holes, and each of the plurality of second via hole groups comprises one or more second via holes; the first line segments and the transfer parts are connected at the first via holes, and the first connecting parts and the transfer parts are connected at the second via holes; and the first via hole groups and the second via hole groups are arranged alternately along the first direction.

2. The array substrate according to claim 1, further comprising a gate driving circuit disposed on one side of the first line segments in a second direction, wherein the gate driving circuit comprises a plurality of cascaded gate driving units arranged along the first direction;
each of the second line segments further comprises second connecting parts each connected to the first connecting part and the gate driving circuit; and
each of the second connecting parts extends along the second direction, and the second direction intersects the first direction.

3. The array substrate according to claim 2, wherein the gate driving units are connected to the second connecting parts in an one-to-one correspondence, and in the first direction, and two adjacent ones of the second connecting parts connected to a same first connecting part are connected to non-adjacent ones of the gate driving units.

4. The array substrate according to claim 2, wherein in the first direction, adjacent ones of the gate driving units are connected to different first connecting parts through different second connecting parts.

5. The array substrate according to claim 2, wherein the first connecting part comprises first sub-parts and second sub-parts;
along the first direction, each of the second sub-parts is connected between two adjacent ones of the first sub-parts;
an orthographic projection of the second via hole groups on the second wiring layer is located within the first sub-parts; and each of the second connecting parts is connected to one of the first sub-parts.

6. The array substrate according to claim 5, wherein a width of each of the first sub-parts is greater than a width of each of the second sub-parts, the first via hole groups are located on one side of the second sub-parts away from the gate driving circuit, and an orthographic projection of the first via hole groups on the first wiring layer is located within the first line segments.

7. The array substrate according to claim 5, wherein each of the first sub-parts comprises a first end close to the gate driving circuit, and the second sub-parts are integrated with the first sub-parts at the first ends;
one lateral surface of the second sub-parts close to the gate driving unit and one lateral surface of the first sub-parts close to the gate driving unit are located in a same plane; and
an orthographic projection of the first connecting part on the first wiring layer presents a comb shape.

8. The array substrate according to claim 5, wherein in the first direction, in a same first connecting part, at least one of the first sub-part that is not connected to the second connecting parts is provided between adjacent ones of the first sub-parts those connected to the second connecting parts.

9. The array substrate according to claim 5, wherein in the first direction, a number of the first via holes in each of the first via hole groups is one, and a number of the second via holes in each of the second via hole groups is one; and
in the second direction, a number of the first via holes in each of the first via hole groups is one, and a number of the second via holes in each of the second via hole groups is one.

10. The array substrate according to claim 9, wherein a sum of areas of orthographic projections of the second via holes in one of the second via hole groups corresponding to any one of the first sub-parts connected to the second connecting parts of the second line segments on the transfer parts is greater than a sum of areas of orthographic projections of the first via holes in one of at least some of the first via hole groups on the transfer parts.

11. The array substrate according to claim 2, wherein the first connecting part is connected to one of the first line segments, and an orthographic projection of the first connecting part on the first wiring layer partially overlaps a corresponding one of the first line segments.

12. The array substrate according to claim 11, wherein the first connecting part is arranged corresponding to one of the first line segments;
in the second direction, one lateral surface of the first connecting part close to the gate driving circuit is located between one lateral surface of a corresponding one of the first line segments close to the driving circuit and the gate driving circuit; and
in the second direction, one lateral surface of the first connecting part away from the gate driving circuit is located between two opposite lateral surfaces of the corresponding one of the first line segments.

13. The array substrate according to claim 11, wherein the first connecting part is arranged corresponding to one of the first line segments;
in the second direction, one lateral surface of the first connecting part close to the gate driving circuit is located between one lateral surface of a corresponding one of the first line segments close to the driving circuit and the gate driving circuit; and
in the second direction, one lateral surface of the first connecting part away from the gate driving circuit is located on one side of one lateral surface of the corresponding one of the first line segments away from the gate driving circuit away from the gate driving circuit.

14. The array substrate according to claim 11, wherein the first connecting part is arranged corresponding to one of the transfer parts and corresponding to one of the first line segments;
in the second direction, one lateral surface of each of the transfer parts close to the gate driving circuit is located on one side of a corresponding one of the first connecting parts away from a corresponding one of the first line segments; and
in the second direction, one lateral surface of each of the transfer parts away from the gate driving circuit is located on one side of the corresponding one of the first line segments away from the gate driving circuit.

15. The array substrate according to claim 14, wherein along a direction from the first line segments to the gate driving units, a number of the first via holes between different first line segments and the transfer parts 108 decreases, and a number of the second via holes between different first connecting parts and the transfer parts decreases.

16. The array substrate according to claim 2, wherein in one of the second via hole groups corresponding to one of the first sub-parts connected to the second connecting parts of the second line segments, a number of the second via holes is greater than or equal to 2; and
in the second direction, a number of the first via holes in each of the first via hole groups is one, and a number of the second via holes in each of the second via hole groups is one.

17. The array substrate according to claim 16, wherein in the first direction, a number of the second via holes in each of the second via hole groups greater than or equal to 2.

18. The array substrate according to claim 1, wherein an orthographic projection of the first via holes on a plane at least partially overlaps an orthographic projection of the second via holes on the plane, and the plane is perpendicular to the first direction and perpendicular to another plane where the array substrate is located.

19. The array substrate according to claim 1, wherein the array substrate further comprises thin film transistors, and each of the thin film transistors comprises a gate, a source, and a drain; the source and the gate are arranged in different layers, the source and the drain are arranged in the same layer, the gate is located in the first wiring layer, and the source and the drain are located in the second wiring layer.

20. A display panel, comprising an array substrate, and the array substrate comprising:
a first wiring layer, comprising first line segments each extending along a first direction;
a second wiring layer, arranged in a different layer from the first wiring layer and comprising second line segments, wherein each of the second line segments comprises a first connecting part extending along the first direction;
an insulating layer, covering the first line segments and the second line segments; and
a transfer layer, disposed on one side of the insulating layer away from the first wiring layer and comprising transfer parts each extending along the first direction,
wherein the insulating layer comprises a plurality of first via hole groups and a plurality of second via hole groups, each of the plurality of first via hole groups comprises one or more first via holes, and each of the plurality of second via hole groups comprises one or more second via holes; the first line segments and the transfer parts are connected at the first via holes, and the first connecting parts and the transfer parts are connected at the second via holes; and the first via hole groups and the second via hole groups are arranged alternately along the first direction.
